(19) United States
(12) Patent Application Publication
(10) Pub. No.: US 2023/0117648 A1
(43) Pub. Date: Apr. 20, 2023

(54) NOVEL COATING FOR CORROSION AND WEAR PROTECTION OF TEMPORARY DOWNHOLE ARTICLE DURING CONVEYANCE AND OPERATION

(71) Applicants: CNPC USA CORPORATION, Houston, TX (US); Beijing Huamei Inc., Beijing (CN)

(72) Inventors: Timothy Dunne, Pearland, TX (US); Lei Zhao, Houston, TX (US); Jiaxiang Ren, Katy, TX (US); Peng Cheng, Sugar Land, TX (US); Yu Liu, Beijing (CN)

(21) Appl. No.: 17/503,289

(22) Filed: Oct. 16, 2021

(51) Int. Cl. C23C 28/00; B05D 5/00; B05D 7/00; C25D 11/02; C25D 11/24; C25D 11/30

(52) U.S. Cl. CPC C23C 28/345; B05D 5/00; B05D 7/56; C23C 28/36; C25D 11/026; C25D 11/246; C25D 11/30; B05D 2202/40

(57) ABSTRACT

The patent application discloses a degradable composite with coatings. The light metal workpiece with enhanced surface protection may comprise a light metal matrix having an exposed surface; a light metal oxide ceramic layer formed in at least a portion of the exposed surface; and a non-transparent metal alloy layer directly on the light metal oxide ceramic layer.

### TECHNICAL FIELD

The present invention relates to isolating zones in a wellbore. More particularly, the present invention relates a coating composition of a downhole tool component for temporary isolation of zones in a wellbore.

### BACKGROUND

Within a wellbore, the hydrocarbons are located at particular depths within a rock formation. These depths can be organized into production zones so that the delivery of production fluids can be targeted to the location of the hydrocarbons. The production fluids facilitate the recovery of the hydrocarbons from the wellbore. Other depth levels do not contain hydrocarbons, which can be called “non-productive zones”. There is no need to waste production fluids on non-productive zones without hydrocarbons. Thus, the productive zones are isolated from the non-productive zones for the recovery of hydrocarbons from the wellbore.

There are known downhole tools to separate a production zone from a non-productive zone. For example, a plug creates a barrier between two zones as a seal between a production zone and a non-productive zone. A ball or frac ball is a very conventional mechanical component for the physical barrier between the zones in a plug.

The barriers or seals between zones are temporary. Thus, these plugs and other downhole tools must be removeable. The typical removal process is milling. A removal assembly, such as a milling unit on a drill string or other wireline device, has a milling or drilling element to drill through components of the plug. The milling unit destroys the components into remnants. The remnants may fall further into the wellbore and can be circulated to the surface by drilling mud.

Conventional materials of the millable plug, like all downhole tools, must withstand the range of wellbore conditions, including high temperatures and/or high pressures. High temperatures are generally defined as downhole temperatures generally in the range of 200-450 degrees F.; and high pressures are generally defined as downhole pressures in the range of 7,500-15,000 psi. Other conditions include pH environments, generally ranging from less than 6.0 or more than 8.0. Metallic components have the durability to withstand the wellbore conditions, including high temperatures and high pressures. Non-metallic components are substituted for metallic components as often as possible to avoid having so much metal to be milled for removal. Composite materials are known to be used to make non-metallic components of the bridge plug. These composite materials combine constituent materials to form a composite material with physical properties of each composite material. For example, a polymer or epoxy can be reinforced by a continuous fiber such as glass, carbon, or aramid.

Dissolvable materials are another alternative for components of downhole tools. When dissolvable materials form a component, that component still must withstand the range of wellbore conditions to function as a plug or other barrier, while also being able to degrade. The degradation is dynamic and quick. The component should dissolve in less than five days within the wellbore. Various patents and patent publications have been issued in the technology for controlling the degradation of dissolvable components in the oil and gas industry.

U.S. Pat. No. 8,276,670, issued on Oct. 2, 2012 to Patel, describes a stopper made of dissolvable materials. U.S. Pat. No. 4,890,675, issued on Jan. 2, 1990 to Dew, describes a generic dissolvable plug to isolate a zone in horizontal drilling. U.S. Pat. No. 5,709,269, issued on Jan. 20, 1998 to Head, discloses another generic dissolvable component, including a locking member and a sleeve. Magnesium and aluminum alloys have been identified as dissolvable materials for components in the oil and gas industry. Known triggering means for a dissolvable component includes a pressure change, wellbore fluid manipulation, or introduced component.

Beyond manipulation of the composition of the dissolvable components, the control of the dissolving has also been modified by coatings. Since the dissolving of the component is relatively sudden (less than five hours) and dynamic by known means to trigger dissolution. A coating can protect the dissolvable component so that the component cannot be triggered to dissolve until the component is properly placed in the wellbore. Premature degradation or losing the potency of the dissolving in response to the trigger can be avoided with a coating.

The conventional coatings are fluoropolymer coatings. The composition of the fluoropolymer coating is a mixture of resins and fluoropolymer lubricants. The fluoropolymer coating provides corrosion and chemical resistance. These fluoropolymer coatings are generic for industrial purposes and have been used in a wide range of industries. In the oil and gas industry, these fluoropolymer coatings have been serviceable. The conveyance period for placement in the wellbore from the surface is relatively quick at less than eight hours. The fluoropolymer coating can remain intact within that range of time under the high temperature and high pressure wellbore conditions and then degrade so that the dissolvable component can be triggered to dissolve as known in the prior art.

The prior art coating compositions in the oil and gas industry remain intact for short amounts of time (about eight hours). However, there are operations that require more than eight hours for conveyance period in the wellbore. There can be extended conveyance periods and extended wait time at the downhole location within the wellbore as well. A plug or other component may need to wait for over thirty days before being activated. Additionally, the component as the dissolvable material must remain reactive to the prior art trigger to dissolve the component. A coating must protect the potency of the material composition of the dissolvable component to dissolve. The shorter duration of less than eight hours will not protect against early exposures to degrade the dissolvable component, such that the potency of the dissolvability is not protected over the longer conveyance periods and extended wait times. These longer conveyance periods and extended wait times are not compatible with the prior art coatings for downhole tools. A different coating composition is needed.

An alternative to the short-lived fluoropolymer coating is an electroless nickel coating. The electroless nickel coating has longer durability and preserves the dissolvability of the component. Various patents and patent publications have been issued in the technology for coating dissolvable components with electroless nickel. US Patent Publication No. 20090223829, published for Gao et al. on Sep. 10, 2009, discloses a method for applying electroless nickel coating on oxide coating over an aluminum or magnesium substrate. U.S. Pat. No. 5,470,664, issued to Bartak et al on Nov. 28, 1995, describes another process for coating magnesium and magnesium alloys. International Patent Publication WO2015015524, published for Fischetto on Feb. 5, 2015, discloses yet another process for coating magnesium alloys with electroless nickel.

The electroless nickel coating also requires its own triggering mechanism, including but not limited to a pressure change, wellbore fluid manipulation, or introduced component. A trigger for the coating will cause a failure of coating, allowing wellbore fluid and/or other methods to corrode the underlying substrate.

It is an object of the present invention to provide a coating composition that prevents corrosion of a dissolvable component for over eight hours in wellbore conditions.

It is an object of the present invention to provide a coating composition that prevents corrosion of a dissolvable component for over thirty days in wellbore conditions.

It is an object of the present invention to provide a coating composition of a dissolvable component that preserves the potency of the dissolvable component to degrade quickly.

It is an object of the present invention to provide a coating composition of a dissolvable component that has a controlled degradation to expose the dissolvable component.

It is another object of the present invention to provide a coating composition of a dissolvable component that also degrades upon contact with its own triggering means.

These and other objectives and advantages of the present invention will become apparent from a reading of the attached specification.

### BRIEF SUMMARY OF THE INVENTION

In one aspect, one embodiment discloses an article. Embodiments of an article having at least a portion of its surface a multi-layer coating. The multi-layer coating a metal or alloy matrix, a corrosion resistance basecoat, and a top hydrophobic layer. The metal or alloy matrix may have an exposed surface. The corrosion resistance basecoat is on at least a portion of the exposed surface

Optionally in any embodiments, the hydrophobic layer comprises at least one of organopolysiloxane, fluoropolymer, rubber, or combination of thereof.

Optionally in any embodiments, the article further comprises a non-transparent metal alloy layer directly on the corrosion resistance basecoat.

Optionally in any embodiments, the top hydrophobic layer may be directly on the non-transparent metal alloy layer.

Optionally in any embodiments, the article may be comprised of magnesium or aluminum.

Optionally in any embodiments, the organopolysiloxane is a silicone resin.

Optionally in any embodiments, the non-transparent metal alloy layer comprises at least one of chrome, nickel, or combination thereof.

Optionally in any embodiments, the non-transparent metal alloy layer comprises nickel.

In another aspect, one embodiment discloses a light metal workpiece with enhanced surface protection. The light metal workpiece comprises a light metal matrix, a light metal oxide ceramic layer, and a non-transparent metal alloy layer.

Optionally in any embodiments, the light metal workpiece further comprises a sealer coat layer as a top layer of the light metal workpiece directly onto the non-transparent metal alloy.

Further in another aspect, one embodiment discloses a method of providing an enhanced surface coating on a metal or alloy surface. The method may comprise steps of providing a metal or alloy substrate having an exposed surface; generating an oxide layer on the exposed surface of the substrate; and applying a sealer coat layer as a top coat.

Optionally in any embodiments, the substrate comprises magnesium, and generating the oxide layer comprises generating a magnesium oxide ceramic.

Optionally in any embodiments, the method further comprise the step of generating the oxide layer on the exposed surface of the substrate comprises using at least one of a micro-arc oxidation and a plasma electrolytic oxidation process.

Optionally in any embodiments, the method further comprise the step of depositing a metal alloy layer directly onto the oxide layer.

Optionally in any embodiments, the sealer coat layer is applied to the metal alloy layer.

Optionally in any embodiments, the oxide layer comprises a thinner dense layer, an intermediate dense layer, and porous outer layer.

Optionally in any embodiments, the metal alloy layer comprises nickel.

Optionally in any embodiments, the metal or alloy substrate comprises at least one of magnesium or aluminum.

The article remains intact for at least 20 days at 60-450 degrees C. and 1-15 ksi, corresponding to downhole conditions in the wellbore during the conveyance period and extended wait time. The article can be selectively triggered to degrade at least 20 days at 60-450 degrees C. and 1-15 ksi.

Furthermore, the substrate covered by the multi-layer coating remains reactive to its own trigger corresponding to releasing the seal between zones in a wellbore at least 20 days at 60-450 degrees C. and 1-15 ksi. The article is prevented from reacting with potassium compounds, until the composition is removed from the substrate and the substrate is exposed to potassium compounds, such as potassium chloride and potassium formate, associated with downhole conditions.

Embodiments of the present invention include the chemical composition of a multi-layer coating. The multi-layer coating remains intact for at least 20 days at 60-450 degrees C. and 1-15 ksi and can be triggered to degrade after at least 20 days at 60-450 degrees C. and 1-15 ksi. The substrate coated with the composition with silicone top layer remains reactive to a respective trigger at least 20 days at 60-450 degrees C. and 1-15 ksi. The substrate coated with the composition with silicone top layer is prevented from reacting with potassium compounds at least 20 days at 60-450 degrees C. and 1-15 ksi.

Alternative embodiments of the present invention include the multi-layer coating can be comprised of 20-40 micrometer thickness of electroless nickel and 2-12% by weight of phosphorous. Similarly, there can be 2-4% by weight of substrate oxides. The thickness of the composition also remains intact, reacts to a trigger, preserves the substrate to react to its own trigger, and prevents the substrate from reacting with potassium compounds, under the downhole conditions for at least 20 days.

The method of forming the coating composition is also an embodiment of the present invention. The method includes pre-treating a substrate by plasma electrolytic oxidation so as to form substrate oxides on a surface of a substrate, and plating electroless nickel at 88-98% by weight and phosphorous at 2-12% by weight on the surface of the substrate. The method of forming the coating composition allows the coating composition to withstand downhole conditions for at least 20 days.

### BRIEF DESCRIPTION OF THE SEVERAL VIEWS OF THE DRAWINGS

FIG. 1 is a schematic illustration of an embodiment according to one embodiment of the present invention.

FIG. 2 is a photographic illustration of embodiments of (a) the PEO coating surface; (b) cross section view of PEO coating surface; and (c) schematic view of different layers of PEO coating.

FIG. 3 is a schematic showing of (a) poor sealer (b) high quality sealer microstructure.

FIG. 4 is cross-sectional optical microscope images of (a) thermoset sealed PEO coating and (b) high magnification optical image of coating microstructure.

FIG. 5 is a schematic illustration of an embodiment according to one embodiment of the present invention.

FIG. 6 is a flow chart of a method of providing an enhanced surface coating on a metal or alloy substrate according to one exemplary embodiment.

FIG. 7 is a photographic illustration of two embodiments of the chemical composition, one without substrate oxides and one with substrate oxides, according to the present invention.

FIG. 8 is a photographic illustration of the embodiments of the electroless nickel coatings on magnesium.

FIG. 9 is a graph illustration of the embodiments of the phosphorus contents relation to hardness.

FIG. 10 is a photograph showing PEO-silicone coating on magnesium substrate after soaking in 3% KCl at 150° C. for 2 days.

FIG. 11 is a photograph showing PEO-EN-silicone coating after soaking in 3% KCl at 150° C. for 2 days.

### DETAILED DESCRIPTION OF THE INVENTION

The following description is merely illustrative in nature and is in no way intended to limit the disclosure, its application, or uses. As used herein, the phrase at least one of A, B, and C should be construed to mean a logical (A or B or C), using a non-exclusive logical “or.” It should be understood that steps within a method may be executed in different order without altering the principles of the present disclosure. Disclosure of ranges includes disclosure of all ranges and subdivided ranges within the entire range.

The term “about” means plus or minus 20%, more preferably plus or minus 10%, even more preferably plus or minus 5%, most preferably plus or minus 2%.

The invention is not limited to the particular methodology, protocols, and reagents described herein because they may vary. Further, the terminology used herein is for the purpose of describing particular embodiments only and is not intended to limit the scope of the present invention. As used herein and in the appended claims, the singular forms “a,” “an,” and “the” include plural reference unless the context clearly dictates otherwise.

Unless defined otherwise, all technical and scientific terms and any acronyms used herein have the same meanings as commonly understood by one of ordinary skill in the art in the field of the invention. Although any methods and materials similar or equivalent to those described herein can be used in the practice of the present invention, the preferred methods, devices, and materials are described herein.

The headings (such as “Background” and “Summary”) and sub-headings used herein are intended only for general organization of topics within the present disclosure, and are not intended to limit the disclosure of the technology or any aspect thereof. The recitation of multiple embodiments having stated features is not intended to exclude other embodiments having additional features, or other embodiments incorporating different combinations of the stated features.

As used herein, the word “include,” and its variants, is intended to be non-limiting, such that recitation of items in a list is not to the exclusion of other like items that may also be useful in the materials, compositions, devices, and methods of this technology. Similarly, the terms “can” and “may” and their variants are intended to be non-limiting, such that recitation that an embodiment can or may comprise certain elements or features does not exclude other embodiments of the present technology that do not contain those elements or features.

Spatially relative terms, such as “inner,” “outer,” “beneath,” “below,” “lower,” “above,” “upper,” “on,” and their variants, may be used herein for ease of description to describe one element or feature's relationship to another element(s) or feature(s). Spatially relative terms may encompass different orientations of the device in use or operation. As used herein, when a coating, layer, or material is “applied onto,” “applied over,” “formed on,” “deposited on,” etc. another substrate or item, the added coating, layer, or material may be applied, formed, deposited on an entirety of the substrate or item, or on at least a portion of the substrate or item.

The broad teachings of the present disclosure can be implemented in a variety of forms. Therefore, while this disclosure includes particular examples, the true scope of the disclosure should not be so limited because other modifications will become apparent to the skilled practitioner upon a study of the specification and the following claims.

The article or substrate 18 can be comprised of any suitable material such as plastic, ceramic, metal or metal alloy. The metals include nickel, magnesium, aluminum, copper, steel and zinc. The metal alloys include nickel alloys and brass. In one embodiment the article is part of a frac plug, such as for example, a downhole tool.

In various aspects, the present teachings provide a light metal workpiece, such as a light metal or metal alloy, with enhanced surface protection. In certain aspects, the light metal workpiece may be a component subjected to exposure to a corrosive environment.

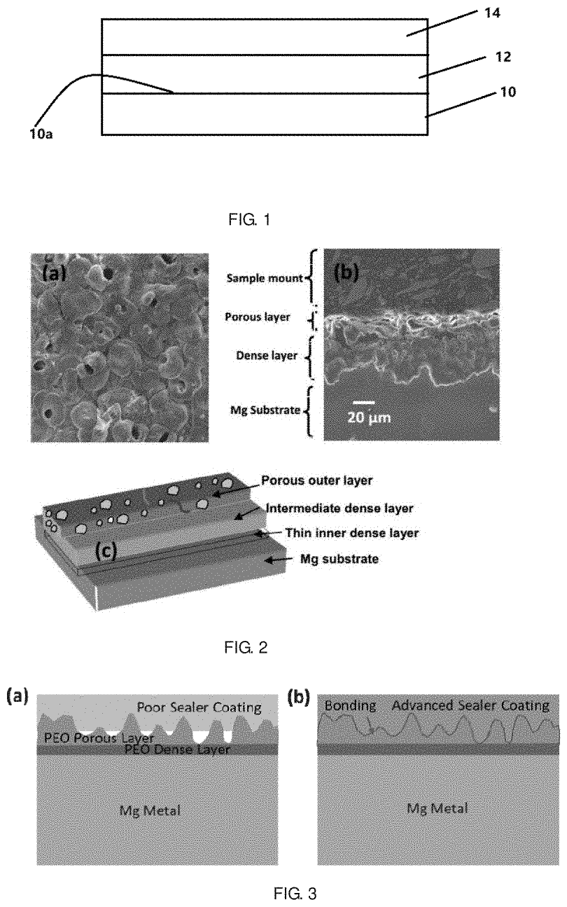

Reference number 10 of FIG. 1 generally indicates the material comprising a light metal, such as a metal matrix, which initially has an exposed surface 10a. The light metal workpiece having the exposed metal surface 10a may undergo various cleaning processes as known in the art, including degreasing, descaling, neutralization, and similar washing processes. In various aspects, a corrosion resistance basecoat 12 may be applied to the metal or metal matrix, followed by a protective enhancing topcoat 14. As shown in FIG. 1, the corrosion resistance basecoat 12 may be applied or formed on the exposed surface 10a. For example, the corrosion resistance basecoat 12 may be a corrosion resistant oxide layer formed on at least a portion of the exposed surface 10a using a micro-arc oxidation or plasma electrolytic technique. A top hydrophobic layer 14 may be applied onto the corrosion resistance basecoat 12 formed of oxides and may be configured to seal the corrosion resistance basecoat 12. As will be discussed in more detail below, the hydrophobic layer 14 may include at least one of an electrostatic coating and a powder material coating. As is known in the art, the top hydrophobic layer 14 may include one or more coatings that impart a desired color/tint, shine, and/or gloss to the workpiece.

As is known in the art, micro-arc oxidation techniques (“MAO”), sometimes also referred to as plasma electrolytic oxidation (“PEO”), spark anodizing, discharge anodizing, or other combinations of these terms, may involve the use of various electrolytes to work in an electrolytic cell and that help generate a porous oxide layer, or porous oxide ceramic layer, at the exposed surface of metal matrix. By way of example, where the workpiece includes aluminum, the oxide layer or oxide ceramic layer may be formed using MAO or PEO techniques to yield a layer of alumina or an alumina ceramic, magnesium oxide or magnesium nitride, the composition of which may vary based on the electrolyte and other materials present therein. Where the workpiece includes magnesium, the oxide layer or ceramic oxide layer may be formed using MAO or PEO techniques to yield a layer of magnesia or magnesium oxide ceramic. There are many patented and commercial variants of the MAO and PEO processes, including those described in U.S. Pat. Nos. 3,293,158; 5,792,335; 6,365,028; 6,896,785; and U.S. patent application Ser. No. 13/262,779, published as U.S. Pub. Pat. App. No. 2012/0031765. In one example, the MAO or PEO process may be performed using a silicate-based electrolyte that may include sodium silicate, potassium hydroxide, and potassium fluoride.

As is generally known in the art, the presence of micropores and/or cracks on the surface of MAO or PEO coatings can be considered to potentially be detrimental and present a weakness with respect to corrosion, as shown in FIG. 2. The presence of a higher pore density on the surface of the MAO or PEO coatings increases the effective surface area and thus the tendency of a corrosive medium to adsorb and concentrate into these pores. However, the presence of a porous outer layer in MAO or PEO coatings can also serve as an advantage by significantly improving the mechanical interlocking effect, the bonding area, and stress distribution, resulting in higher bond strength. In view of the potential susceptibility to corrosion due to higher effective surface area and porosity, the pore density, distribution of pores and interconnectivity of the pores with the remainder of the substrate can be important factors. In various aspects of the present disclosure, the corrosion resistance basecoat 12 may be generated or formed having a controlled and substantially uniform porosity of from about 0.1 μm to about 5 μm, from about 1 μm to about 3 μm, or from about 0.1 μm to about 1 μm, for example. The oxide layer 12 may be generated or formed having a substantially uniform thickness of from about 2 μm to about 30 μm, from about 4 μm to about 25 μm, or from about 5 μm to about 20 μm, for example.

Further in FIG. 2, the oxide PEO layer comprises a thinner dense layer, an intermediate dense layer, and porous outer layer, for example. The thin inner dense layer is the closest layer to the Mg substrate.

With regard to the above-mentioned potential weakness of the MAO or PEO coatings, a sealing coating is applied to the porous oxide or ceramic layer from the MAO or PEO process. As such, the present disclosure applies a top hydrophobic layer 14 over the oxide layer 12. In various aspects, the top hydrophobic layer 14 may be an electrostatic coating layer, or electrostatic layer, applied onto the oxide layer 12 using an electrocoating technique (“e-coating” or electrophoresis coating) that is configured to seal the corrosion resistance basecoat 12 and provide for increased adhesion of optional additional layers applied thereon. As an alternative to the e-coating, the top hydrophobic layer 14 may include a powder material coating. Prior to the application of the top hydrophobic layer 14, the workpiece may optionally be washed or immersed in deionized water.

In aspects where an e-coating is used as the top hydrophobic layer 14, it should be understood that there are many sealer systems that may be used in conjunction with the MAO and PEO processes, and they may include a wide variety of polymers and resins, including but not limited to, fluoropolymers, acrylic, rubber, epoxy, polyester, polysiloxanes, such as organopolysiloxane, and polyvinylidene fluoride (PVDF). These materials may be applied in the form of electrostatically sprayed coatings, by electrophoretic deposition, or by known dipping or wet spraying techniques. In one presently preferred aspect that can be used with magnesium workpieces, such as magnesium or magnesium alloy downhole tools, an epoxy resin may be used, for example, EPOXY RESIN KATAPHORESIS COATING (EED-060M). Generally, the top hydrophobic layer 14 will not contain a significant amount of any chemically active agent therein. In various aspects, the e-coating treatment process may take place from 0 to about 3 minutes using a voltage of between about 160V to about 220V, and cured at a temperature of from about 160° C. to about 180° C. for a curing time of from about 20 to about 30 minutes. In various aspects, the top hydrophobic layer 14 may be an e-coating or powder material coating applied having a substantially uniform thickness of from about 1 μm to about 200 μm, or from about 50 μm to about 150 μm, or from about 70 μm to about 130 μm, or from about 80 μm to about 120 μm, and in certain aspects, a thickness of about 100 μm, for examples.

When top hydrophobic layer 14 includes an electrostatically applied coating, the approaches adopted with the present teachings include applying top hydrophobic layer 14 on the corrosion resistance basecoat 12 within less than about 30 hours, and preferably less than about 24 hours, less than about 20 hours, or less than about 16 hours after generating or forming the oxide or ceramic oxide corrosion resistance basecoat 12.

As mentioned above, the top hydrophobic layer 14 may be a powdered coating material. Powder coating materials useful herein as the top hydrophobic layer 14 may include thermoplastic or reactive polymers commonly used in the art that are typically solid at room temperature. Most powders are reactive one-component systems that liquefy, flow, and then crosslink as a result of treatment with heat. Common polymers that may be used as powder coating materials include polyester, polyurethane, polyester-epoxy (known as hybrid), straight epoxy (fusion bonded epoxy), and acrylics.

FIG. 3(a) shows poor sealer coating to the PEO porous layer, The poor sealer may include TEFLON, PEEK coatings, for example. FIG. 3(b) shows high quality sealer, having a good bonding between the sealer and PEO porous layer without any unfilled holes or cracks.

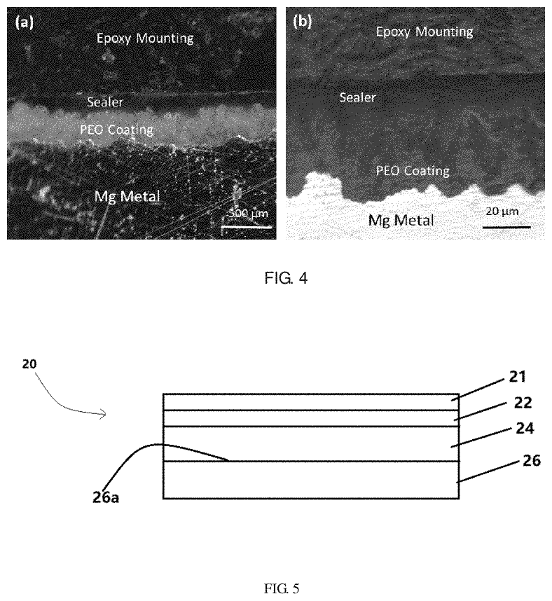

FIG. 4 shows photographic cross-sectional view of good bonding of sealer to the PEO coating on the substrate of Mg metal.

By way of example, in one aspect, the method of applying the powder material coating can include electrostatically spraying a wet black resin powder onto the corrosion resistance basecoat 12 of a heated substrate, the resin powder being delivered at a voltage of from about 40 kV to about 50 kV, or about 45 kV, and a current of from about 0.4 A to about 0.6 A, or about 0.5 A. The methods of the present teachings further include curing and condensing any powder coating layer by placing the workpiece or substrate in a heated environment at a temperature of from about 180° C. to about 200° C., or about 190° C., for a time period of from about 15 minutes to about 25 minutes, or about 20 minutes, for example.

As known in the art, a wide range of materials and methods for encapsulation are commercially available that provide for a variety of strategies to create the degree of durability and corrosion resistance. The approaches adopted with the present teachings include applying a top hydrophobic layer 14 that may include applying another coat or layer. In certain aspects, the entire method may be performed in a single assembly line. In other aspects, the corrosion resistance basecoat layer 12 may be applied in a first assembly, and the top hydrophobic layer 14 may be applied in a second assembly.

In various aspects, another coat or second coat on the top hydrophobic layer may be an e-coating or powder material coating applied having a substantially uniform thickness of from about 1 μm to about 200 μm, or from about 50 μm to about 150 μm, or from about 70 μm to about 130 μm, or from about 80 μm to about 120 μm, or about 100 μm, for example. In certain aspects, top hydrophobic layer 14 can be applied onto the corrosion resistance basecoat 12 having a first thickness, and the another or second top hydrophobic layer or coating can be applied onto the top hydrophobic layer 14 having a second thickness. The first thickness may be substantially equal to or slightly less than the second thickness. The second top hydrophobic layer may be the same material as the first top hydrophobic layer 12, or it may be a different material from the first top hydrophobic layer 12. Both coatings may be e-coatings, both coatings may be powder coating layers, or one of the coatings may be an e-coating, while the other coating may be a powder material coating. Further, multiple layers of each coating may be formed. In instances where top hydrophobic layer 14 is an electrocoating and the second top hydrophobic layer 14 is a powder material coating, it may be beneficial to have a powder material coating having a thickness much greater than the electrocoating in order to provide increased corrosion protection.

Thus, the approaches adopted with the present teachings may include applying the second top hydrophobic layer or coating having a second thickness of from about 1.5 to about 10 times greater than the first top hydrophobic layer. Accordingly, by way of example, in certain aspects a first top hydrophobic layer having a thickness of about 15 μm may be used with a second top hydrophobic layer having a thickness of from about 25 μm to about 150 μm, for example.

In various aspects, the methods of the present teachings may include heating the workpiece or substrate having a top hydrophobic layer 14 to a temperature of from about 80° C. to about 100° C. prior to applying the second top hydrophobic layer.

In another embodiment of the invention, as shown in FIG. 5, a light metal workpiece 20 with enhanced surface protection may include a light metal matrix 26, a light metal oxide ceramic layer 24, and a non-transparent metal layer 22. The light metal oxide ceramic layer 24 may be applied to a part of exposed surface 26a of the light metal matrix 26. The non-transparent metal layer 22 may be directly on the light metal oxide ceramic layer 24.

Additionally, the light metal workpiece 20 may further comprise a sealer coat layer 21 as a top layer of the light metal workpiece, which may be directly on the non-transparent metal layer 22. The sealer coat layer 21 may comprise at least one of organopolysiloxane, fluoropolymer, rubber, or combination of thereof.

In one embodiment, the non-transparent metal alloy layer comprises at least one of chrome, nickel, or combination thereof. In another embodiment, the non-transparent metal alloy layer comprises nickel, for example.

The non-transparent metal layer 22 may be deposited on light metal oxide ceramic layer 24 by any of the conventional and well known method.

A variety of depositing methods may be employed to apply the metal compositions that form the metal layer or metal film 22 on the light metal oxide ceramic layer 24. One method is with sputter deposition techniques. Sputter deposition is an ion-assisted, physical vapor deposition (PVD) technique of depositing thin films by sputtering. This typically involves ejecting material from a “target” that is a source onto a “substrate” such as the on the light metal oxide ceramic layer 24 on a workpiece. In certain aspects, the physical vapor deposition may be open air plasma assisted physical vapor deposition or ion beam assisted physical vapor deposition.

Preferred metals for the non-transparent metal layer 22 include, for example, chromium (Cr) or compounds of Cr, such as chromium nitride (CrN), and nickel (Ni) or compounds of Ni. As recognized by one of skill in the art, the metal film composition may comprise mixtures of the above identified metals, as well.

It is envisioned that various ion-assisted PVD apparatuses can be used to apply the non-transparent metal layer 22. One exemplary apparatus may include a deposition chamber and one or more electron guns for deposition of the metal film. As is known in the art, in certain aspects, the apparatus may be operated in an ultra-high vacuum. The substrate to be coated with the metal film may be first placed in a chamber and the pressure is lowered. A first crucible in the chamber may hold the metal to be deposited. If a combination of metals is to be deposited, a second metal may be held by a second crucible, which is deposited over the first layer, forming a second layer. Another option available may be to deposit a combination of metals simultaneously. Metals may be deposited on the light metal oxide ceramic layer 24 at a rate of about 0.10 nm/s to a thickness of greater than about 1 nm and less than about 50 nm, which can be observed by thickness monitors known in the art. The non-transparent metal layer 22 may have been deposited onto the light metal oxide ceramic layer 24 at ultra-low thicknesses of less than about 50 nm, optionally less than about 40 nm, or in certain aspects, at about 25 nm to about 30 nm, for example. In certain aspects, it may be possible to coat a very thin layer, for example, an ultra-thin layer on the order of from about 1 nm to about 20 nm, from about 5 nm to about 15 nm, or about 10 nm, still achieving good surface coverage, substantially uniform coverage, and good adhesion. Accordingly, the use of PVC allows the non-transparent metal layer 22 to be deposited on the light metal oxide ceramic layer 24 very smoothly, evenly, and in a thin layer.

Other suitable PVC methods may include magnetron sputtering, where a target (the corrosion resistance basecoat 12) is bombarded with a sputter gun in an argon ion atmosphere, while the substrate is charged. The sputter gun forms a plasma of metal particles and argon ions that transfer by momentum to coat the substrate. Still other methods of applying the non-transparent metal layer 22 may include electron beam evaporation, where the substrate is contained in a vacuum chamber (from between about 10⁻³ to 10⁻⁴ Torr or about 1.3×10⁻¹ Pa to 1.3×10⁻² Pa) and a metal evaporant is heated by a charged electron beam, where it evaporates and then condenses on the target substrate. The metal film 22 may also be applied by electroplating (e.g., electrolytic deposition), electroless deposition/plating, or pulse laser deposition.

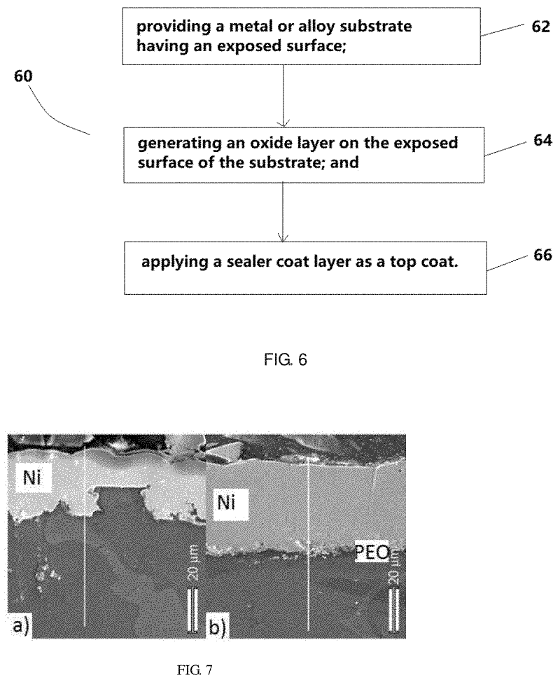

As shown in FIG. 6, a method 60 providing an enhanced surface coating on a metal or alloy substrate may comprise: step 62 of providing a metal or alloy substrate, such as magnesium or aluminum, having an exposed surface; step 64 of generating an oxide layer on the exposed surface of the substrate; and step 66 of applying a sealer coat layer as a top coat. The substrate comprises magnesium, for examples. The step of generating the oxide layer may comprise generating a magnesium oxide ceramic, by various methods. More specifically, the step 64 of generating the oxide layer on the exposed surface of the substrate comprises using at least one of a micro-arc oxidation and a plasma electrolytic oxidation process.

The method 60 may further comprise a step of depositing a metal layer, such as nickel, directly onto the oxide layer, such as MgO, and the sealer coat layer may be applied to the metal layer. The oxide layer, such as MgO, may comprise a thinner dense layer, an intermediate dense layer, and porous outer layer, for example, as shown in FIG. 2. The sealer coat layer may comprise at least one of organopolysiloxane, fluoropolymer, rubber, or combination of thereof.

FIG. 7(a) shows a cross-sectional view of an electroless nickel coated magnesium material. FIG. 7(b) shows a cross-sectional view of a magnesium substrate that was initially treated via the plasma electrolytic oxidation (PEO) technique. Subsequently, the nickel coating was applied over the PEO coating.

Over the nickel layer is applied a sealer coat layer. The silicone resins or organopolysiloxanes which are utilized in the instant invention are conventional, well known and generally commercially available. They are disclosed, inter alia, in U.S. Pat. Nos. 3,375,223; 3,435,001; 3,450,672; 3,790,527; 3,832,319; 3,865,766; 3,888,815; 3,887,514; 3,925,276; 3,986,997; and 4,027,073.

The silicone resin is applied from a sealer coat layer composition containing a further-curable organopolysiloxane and, generally, solvents for the further curable organopolysiloxane. The sealer coat layer composition may be applied by standard and conventional techniques such as spraying, brushing, etc. over the non-transparent metal layer.

To cure the further curable organopolysiloxane and form the silicone resin top coat, the top coat composition is then heated at a temperature and for a time effective to cure said further curable organopolysiloxane.

One particular class of further curable organopolysiloxanes which are employed in the top coat compositions of the present invention are the partial hydrolysis and condensation products of alkoxy functional silanes, preferably alkyltrialkoxysilanes, preferably those alkyltrialkoxysilanes wherein the alkyl group contains from 1 to about 8 carbon atoms, and aryltrialkoxysilanes, preferably phenyltriakoxysilanes, or mixtures thereof, wherein the alkoxy group contains from 1 to about 8 carbon atoms, such as, for example, methoxy, ethoxy, isopropoxy, butoxy, pentoxy, hexoxy, octoxy, and the like. These further-curable organopolysiloxanes are generally prepared by a process wherein the alkyltrialkoxysilane and aryltrialkoxysilane is heated in the presence of water, wherein the molar ratio of water to total silane is at least about 1.5:1 and in the presence of an effective amount of a hydrolysis catalyst, such as a mineral acid, for example, HCl, for about 1 to about 10 hours at a temperature between ambient and reflux to produce a siloxane partial condensation product; the partial condensation product is then concentrated by heating to remove 50 to about 90 mole percent alkanol by-product and some water, and thereafter, the concentrated partial condensation product is precured by heating at a temperature below the gel point thereof and generally in the range of about 70° C. to 300° C. to produce the solvent-soluble, further curable organopolysiloxane. This precured solvent-soluble, further curable organopolysiloxane is then dissolved in a suitable solvent to form the top-coat composition and the non-transparent metal layer 22 is then coated with this top coat composition.

The solvent is then evaporated and the residual further curable organopolysiloxane is cured to a thermoset state to provide a top coat. The curing is effected at elevated temperatures in the range of about 50° C. to 135° C. for times between about 1 hour to about 72 hours, depending on the temperature at which the cure is effected. The silicone top coat generally should be cured preferably at an elevated temperature to effect the proper cure.

One particular further curable organopolysiloxane that can be employed in the top coat composition of the instant invention is the partial hydrolysis and condensation product of methyltriethoxysilane. This further curable organopolysiloxane is prepared by hydrolyzing methyltriethoxysilane with water in the presence of an effective amount of a hydrolysis catalyst, such as HCl, for about 1 to 10 hours at a temperature generally between 40° C. and reflux temperature, to product a partial condensation product. This partial condensation product is then concentrated by heating to remove some of the alkanol by-product and water. This concentrated product is then partially pre-cured at a temperature of about 70° to about 300° C. and below the gel point thereof and then solidified to provide a solid, solvent-soluble, further curable organopolysiloxane is then dissolved to a desired concentration in a suitable solvent to form the top coat composition. The top coat composition is then applied to the primed polycarbonate substrate, after which the solvent is evaporated and the further curable organopolysiloxane finally cured to provide a hard, abrasion and chemical solvent resistant, thermoset organopolysiloxane top coat on the polycarbonate substrate.

Another further curable organopolysiloxane which may be employed in the practice of the present invention is the partial hydrolysis and condensation product of a mixture of methyltriethoxysilane and phenyltriethoxysilane. This organopolysiloxane is prepared by hydrolyzing a mixture of methyltriethoxysilane and phenyltriethoxysilane with water in the presence of a hydrolysis catalyst such as HCl to produce a partial condensation product. This partial condensation product is then concentrated by heating to remove a substantial amount of the alkanol by-product and some water. This concentrated product is then partially pre-cured by heating and then solidified to provide a solid, solvent-soluble, further curable organopolysiloxane.

The solid, solvent-soluble, further curable organopolysiloxane is then dissolved to a desired concentration in a suitable solvent to form the top coat composition containing a further curable organopolysiloxane. The top coat composition is then applied to the primed polycarbonate substrate, after which the solvent is evaporated and the further curable organopolysiloxane is finally cured to provide a tenaciously and durably adhered, abrasion and chemical resistant thermoset organopolysiloxane top coat on the polycarbonate substrate.

These are not the only silicones that may be utilized in the top coats of the instant invention. Also useful are silicone resins composed of trifunctional and difunctional units, silicone resins composed of trifunctional units, difunctional units and tetrafunctional units where the organo substituent groups in the trifunctional units may be selected from hydrocarbon radicals of 1 to about 8 carbon atoms and are preferably methyl, phenyl and vinyl; and wherein the organo substituent groups in the difunctional siloxy units may be selected from hydrocarbon units of from 1 to about 8 carbon atoms, preferably alkyl radicals, vinyl radicals and phenyl radicals. Such silicone resins usually have an organic to silicone atom ratio of 1:1 to 1.9:1, may have a silanol content that varies anywhere from 4 to 10 weight percent and optionally may have an alkoxy content that varies from 2 to 4%. The preparation of such silicone resins which may be utilized as top coats in the invention of the instant case are, for instance, to be found in U.S. Pat. Nos. 3,375,223; 3,435,001; 3,450,672; 3,790,527, 3,832,319; 3,865,766; 3,887,514 and 3,925,276.

These silicones may also contain fillers such as, for example, glass, talc and silica, preferably colloidal silica.

The coating compositions containing the afore-described silicones are simply brushed, dipped, sprayed or flowed on the top. The solvent, or alcohol by-product and water, present in the top coat composition is evaporated and the residual further curable organopolysiloxane is cured to form a thermoset organopolysiloxane top coat. Preferably, the further curable organopolysiloxane is cured at elevated temperatures. Although certain catalysts may be utilized to accelerate the cure of the further curable organopolysiloxane, such catalysts are not necessary if the further curable organopolysiloxane is cured by itself at the elevated temperature for a sufficient length of time.

The sealer coat layer as a top coat can also be applied by well known, standard and conventional chemical vapor deposition, particularly plasma enhanced chemical vapor deposition, processes and physical vapor deposition sputtering processes.

Chemical vapor deposition (CVD) is defined as the formation of a non-volatile solid film on a substrate by the reaction of vapor phase reactants that contain desired components. The gases are introduced into a reactor vessel, and decompose and react at a heated surface on the substrate to form the desired film.

CVD is generally classified into one of three types. The first two are principally predicated upon reactor pressure, and are designated as atmospheric pressure chemical vapor deposition (APCVD) or low pressure chemical vapor deposition (LPCDV).

A third category is referred to as plasma enhanced chemical vapor deposition (PECVD). Rather than relying solely on thermal energy to initiate and sustain chemical reactions, PECVD uses a radio frequency (RF) induced glow discharge or direct current or microwaves to transfer energy into the reactant gases, allowing the substrate to remain at lower temperature than in APCVD or LPCVD processes. Specifically, the plasma-inducing glow discharge is generated by the application of an RF field to a low pressure gas, thereby creating free electrons within the discharge region. The electrons gain sufficient energy from the electric field so that when they collide with gas molecules, gas-phase dissociation and ionization of the reactant gases (i.e., inducement into the plasma state) then occurs. Lower substrate temperature is the major advantage of PECVD, and provides a method of depositing films on some substrates which do not have the thermal stability to accept coating by other methods. In addition, PECVD can enhance the deposition rate when compared to thermal reactions alone, and produces films of unique compositions and properties.

Plasma enhanced chemical vapor deposition processes and reactors are disclosed, inter alia, in U.S. Pat. Nos. 5,646,435; 5,646,050; 4,888,199; 5,628,829; 5,643,364 and 5,628,869.

The thickness of the silicone resin layer is a thickness at least effective to protect the underlying chrome/nickel alloy layer from scratching, abrasion and corrosion, and to give it the appearance of black chrome, i.e., a dark, lustrous and shiny appearance. Generally this thickness is from about 0.05 mil to about 5 mils, preferably from about 0.1 mil to about 3 mils, and more preferably from about 0.2 mil to about 1 mil.

In certain situations, the silicone top coat may not adhere sufficiently well to the light metal oxide ceramic layer. In such cases a primer layer may optionally be applied onto the metal layer and the silicone top coat applied over the primer layer. Polyacrylates and polymethacrylates are useful as primer layers.

The coating protects the component during the conveyance period and wait time in a wellbore. Conventional coatings only protect the component for a few hours, and the conventional coatings immediately begin to degrade in the conveyance period. For conveyance periods longer than about eight hours, the conventional coatings are unreliable. For a wait time in the range of several days and up to 20 days, conventional coatings are even more unreliable and inconsistent. The lack of control for degrading the coating affects the predictability and effectiveness of dissolving the actual component, when needed in the regular coordinated operations of the wellbore.

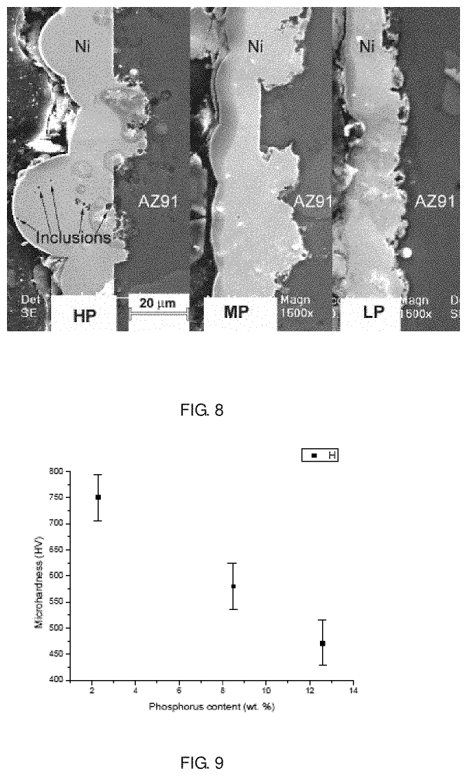

In the present invention, the chemical composition of electroless nickel electrolytic solution is comprised of nickel salt and phosphorous salt. The electrolytic solution may be comprised of 87-98% by weight of nickel and 2-13% by weight of phosphorous. The electroless nickel is plated on a substrate as in FIG. 8, which shows cross-section of electroless nickel applied on magnesium alloy AZ91 with different phosphorous content. HP refers to high phosphorus content. MP refers to medium phosphorus content. LP refers to low phosphorus content.

FIG. 9 shows the result of different amounts of phosphorous within the claimed range correspond to microhardness of electroless nickel. The lower range of phosphorous remains effective. Magnesium oxides are included when the substrate is a magnesium alloy with high phosphorus contents in electrolyte solution. The substrate oxides are formed in a pretreatment step of the substrate by plasma electrolytic oxidation.

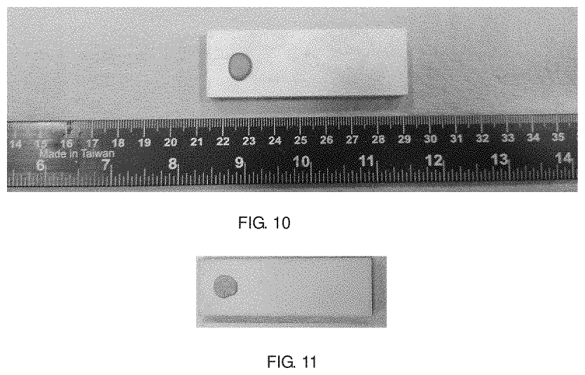

As shown in FIG. 10, the magnesium substrate with PEO-silicone coating remains intact for at least 2 days at 150 degrees C. and 1-15 ksi, corresponding to downhole conditions in the wellbore during the conveyance period and extended wait time. The combination of coatings is adequate for protecting a dissolvable frac plug. Beneficially, there was a uniform degradation of the silicone coating which implies the protection can be a function of the coating thickness. A further combination of electroless nickel on the PEO substrate with the silicone coating would provide better protection. FIG. 11 shows a photograph PEO-EN-silicone coating after soaking in 3% KCl at 150° C. for 2 days. Alternatively, silicone over electroless nickel would provide adequate protection for a frac plug.

The magnesium with a multi-layer coating can be selectively triggered to degrade at least 20 days at 60-450 degrees C. and 1-15 ksi. Additional data support that the composition can be degraded in a controlled manner by a trigger.

The substrate covered by the multi-layer coating remains reactive to its own trigger corresponding to releasing the seal between zones in a wellbore at least 20 days at 60-450 degrees C. and 1-15 ksi. Additional data support that the substrate is intact.

The substrate is prevented from reacting with potassium compounds, until the multi-layer coating is removed from the substrate and the substrate is exposed to potassium compounds, such as potassium chloride and potassium formate, associated with downhole conditions. Additional data support that the composition is functional in the claimed range to prevent the uncontrolled degradation of the substrate.

An alternative embodiment of the present invention is the downhole component comprising a coating composition and the substrate. In this embodiment, the substrate is claimed. The composition of the downhole component is defined in terms of the coating composition being comprised of electroless nickel and phosphorous and the substrate being comprised of a metal alloy. The other variation is to include substrate oxides formed by the plasma electrolytic oxidation.

The coating composition of the present invention prevents corrosion of a dissolvable component for over eight hours in wellbore conditions. The coating composition protects the dissolvable components for the complete conveyance period and wait time in the wellbore conditions. The coating composition is relatively permanent in comparison to prior art coatings. The immediate and uncontrolled degradation of fluoropolymer coatings of the prior art as a “temporary” coating is avoided. The coating composition prevents corrosion of a dissolvable component for over thirty days in wellbore conditions, instead of only for eight hours.

The coating composition has its own trigger. The hardness and effectiveness are maintained through the conveyance period and wait time, until the trigger is delivered to the downhole location.

The coating composition protects the potency of the dissolvable component. With temporary coatings, the dissolvable component may have degraded early or partially. In the operation of the wellbore, the coordinated action of sealing and unsealing zones is more reliable. With an early degraded or partially degraded component, the operations are not as consistent nor reliable. The present invention provides for a coating composition to preserve the control of the dissolving of the dissolvable component, even after several days in the downhole conditions. The exposure the dissolvable component to the downhole conditions is more controlled and regulated for the operation and safety of the wellbore.

The foregoing disclosure and description of the invention is illustrative and explanatory thereof. Various changes in the details of the illustrated structures, construction and method can be made without departing from the true spirit of the invention.

The above shows and describes the basic principles, main features and advantages of the utility patent application. Those skilled in the industry should understand that the present utility patent application is not limited by the above-mentioned embodiments. The above-mentioned embodiments and the description are only preferred examples of the present utility patent application and are not intended to limit the present utility patent application, without departing from the present utility patent application. Under the premise of spirit and scope, the present utility patent application will have various changes and improvements, and these changes and improvements fall within the scope of the claimed utility patent application. The scope of protection claimed by the utility patent application is defined by the appended claims and their equivalents.

We claim:

1. An article having on at least a portion of its surface a multi-layer coating comprising:
a metal or alloy matrix having an exposed surface;
a corrosion resistance basecoat on at least a portion of the exposed surface; and
a top hydrophobic layer.

2. The article of claim 1 wherein the hydrophobic layer comprises at least one of organopolysiloxane, fluoropolymer, rubber, or combination of thereof.

3. The article of claim 1 further comprises a non-transparent metal alloy layer directly on the corrosion resistance basecoat.

4. The article of claim 3 wherein the top hydrophobic layer is directly on the non-transparent metal alloy layer.

5. The article of claim 1 wherein the article is comprised of magnesium or aluminum.

6. The article of claim 1 wherein the organopolysiloxane is a silicone resin.

7. The article of claim 1 wherein the non-transparent metal alloy layer comprises at least one of chrome, nickel, or combination thereof.

8. The article of claim 7 wherein the non-transparent metal alloy layer comprises nickel.

9. A light metal workpiece with enhanced surface protection, comprising:
a light metal matrix having an exposed surface;
a light metal oxide ceramic layer formed in at least a portion of the exposed surface; and
a non-transparent metal layer directly on the light metal oxide ceramic layer.

10. The light metal workpiece 9, further comprising a sealer coat layer as a top layer of the light metal workpiece directly onto the non-transparent metal alloy.

11. The wheel of claim 10, wherein the sealer coat layer comprises at least one of organopolysiloxane, fluoropolymer, rubber, or combination of thereof.

12. A method of providing an enhanced surface coating on a metal or alloy substrate, the method comprising:
providing a metal or alloy substrate having an exposed surface;
generating an oxide layer on the exposed surface of the substrate; and
applying a sealer coat layer as a top coat.

13. The method according to claim 12, wherein the substrate comprises magnesium, and generating the oxide layer comprises generating a magnesium oxide ceramic.

14. The method according to claim 12, wherein generating the oxide layer on the exposed surface of the substrate comprises using at least one of a micro-arc oxidation and a plasma electrolytic oxidation process.

15. The method according to claim 12, further comprising depositing a metal layer directly onto the oxide layer.

16. The method according to claim 15, wherein the sealer coat layer is applied to the metal layer.

17. The method according to claim 12, wherein the oxide layer comprises a thinner dense layer, an intermediate dense layer, and porous outer layer.

18. The method according to claim 12, wherein the sealer coat layer comprises at least one of organopolysiloxane, fluoropolymer, rubber, or combination of thereof.

19. The method according to claim 12, wherein the metal layer comprises nickel.

20. The method according to claim 12, wherein the metal or alloy substrate comprises at least one of magnesium or aluminum.
